(19) United States
(12) Patent Application Publication
(10) Pub. No.: US 2023/0088073 A1
(43) Pub. Date: Mar. 23, 2023

(54) OLED DISPLAY PANEL AND DISPLAY DEVICE

(71) Applicant: Wuhan China Star Optoelectronics Semiconductor Display Technology Co., Ltd., Wuhan (CN)

(72) Inventor: Peng WANG, Wuhan (CN)

(73) Assignee: Wuhan China Star Optoelectronics Semiconductor Display Technology Co., Ltd., Wuhan (CN)

(21) Appl. No.: 16/957,377

(22) PCT Filed: Apr. 7, 2020
(86) PCT No.: PCT/CN2020/083490

§ 371 Date: Jun. 24, 2020

(30) Foreign Application Priority Data
Mar. 19, 2020 (CN) 202010195001.1

(51) Int. Cl. H10K 59/122; H10K 50/86; H10K 50/856; H10K 50/80; H10K 50/813

(52) U.S. Cl. CPC H01L 27/3246; H01L 51/5284; H01L 51/5271; H01L 51/5293; H01L 51/5209; H01L 2251/306

(57) ABSTRACT

The present invention provides an organic light emitting diode (OLED) display panel and a display device. In the present invention, the planarization layer is disposed with a recess, the anode layer fully covers the recess and extend upward along the sidewall of the recess for a predetermined length. The light emitting layer is disposed opposite the anode layer. When the light emitting layer emits out light, a bottom and a side portion of the light emitting layer in a light emitting region generate light, and the light is emitted out at a corresponding angle to increase light emitting area and angle of the light emitting layer and reduce phenomenon of the color shift of the OLED display panel display screen under a great angle of view to increase a viewable angle of view.

### FIELD OF INVENTION

The present invention relates to a field of display technologies, especially relates to an organic light emitting diode (OLED) display panel and a display device.

### BACKGROUND OF INVENTION

Organic light emitting diode (OLED) display panels has features of self-luminescence, high contrast, wide angles of view, fast responsive speeds, etc. A work principle employs an indium tin oxide (ITO) transparent electrode and a metal electrode to serve as an anode and a cathode of the device. Under driving of a certain voltage, electrons and holes are injected respectively through the cathode and the anode into the electron and hole transport layers. The electrons and the holes move to the light emitting layer respectively through electron and hole transport layers and encounter each other in the light emitting layer to form excitons such that the light emitting layer molecules are excited to radiate visible light.

In a common OLED display panel, light emitted from the light emitting layer, after inputted through the encapsulation layer and the cover plate layer, the outputted light has a specific orientation, most light is vertically emitted out from the screen. When the OLED display panel is viewed from other angle, original color is not seen and only blur images or even entirely black or white images can be seen.

As described above, it is required to set forth an OLED display panel to solve the technical issue that emitted light of the conventional OLED display panel is only perpendicular to a certain angle, especially in the curve display, to result in color shift of OLED display panel display screen under a large angle of view and the angle of view is poor.

### SUMMARY OF INVENTION

### Technical Issue

The present invention provides an organic light emitting diode (OLED) display panel and a display device solving the technical issue that emitted light of the conventional OLED display panel is merely perpendicular to a certain angle, especially in the curve display, results in that the OLED display panel display screen has a color shift under a great angle of view and the angle of view is poor.

### Technical Solution

To solve the above issue, the present invention provides technical solutions as follows.

The present invention provides an organic light emitting diode (OLED) display panel, comprising a light emitting region and a non-light emitting region, wherein the OLED display panel comprises: an underlay substrate comprising the light emitting region and the non-light emitting region; a thin film transistor (TFT) layer disposed on a side of the underlay substrate; a planarization layer disposed on a side of the TFT layer away from the underlay substrate, and comprising a first recess defined in the planarization layer and corresponding to the light emitting region; an anode layer comprising a bending portion and a horizontal portion, the bending portion covering a surface of the first recess, the horizontal portion extending from two sides of the first recess to the non-light emitting region, and a second recess defined in a surface of the bending portion and corresponding to the light emitting region; a pixel definition layer located on a side of the planarization layer away from the TFT layer, disposed separately along two extension lines of two side walls of the second recess, and covering the horizontal portion; a light emitting layer disposed on a surface of the second recess and disposed opposite to the bending portion; a cathode layer disposed on and fully covering the light emitting layer and a surface of the pixel definition layer; and an encapsulation layer disposed on a surface of the cathode layer.

According to a preferred embodiment of the present invention, the TFT layer comprises a light shielding layer disposed on a surface of the underlay substrate, a buffer layer disposed on the surface of the underlay substrate and covering the light shielding layer, an active layer disposed on the buffer layer, a first gate insulation layer disposed on the buffer layer and covering the active layer, a first gate electrode disposed on the first gate insulation layer, a second gate insulation layer disposed on the first gate insulation layer and covering the first gate electrode, a second gate electrode disposed on the second gate insulation layer, an interlayer dielectric layer disposed on the second gate insulation layer and covering the second gate electrode, a source electrode and a drain electrode disposed on the interlayer dielectric layer; wherein an anode via hole is defined in a portion of the planarization layer corresponding to the drain electrode, and a side of the horizontal portion is electrically connected to the drain electrode through the anode via hole.

According to a preferred embodiment of the present invention, the planarization layer comprises a first planarization layer and a second planarization layer, and the first recess is located in the second planarization layer.

According to a preferred embodiment of the present invention, the bending portion comprises a first tilt portion, a horizontal connection portion, and a second tilt portion, and the first tilt portion, the horizontal connection portion, and the second tilt portion are formed integrally.

According to a preferred embodiment of the present invention, the first tilt portion and the second tilt portion are symmetrical to a central line of the horizontal connection portion.

According to a preferred embodiment of the present invention, a first included angle is formed between the first tilt portion and the horizontal connection portion, a second included angle is formed between the second tilt portion and the horizontal connection portion, and each of the first included angle and the second included angle is from 30° to 60°.

According to a preferred embodiment of the present invention, an inner wall of the first recess is tilted or curved toward a center of the first recess, and an inner wall of the second recess is tilted or curved toward a center of the second recess.

According to a preferred embodiment of the present invention, a geometrical shape of each of the first recess and the second recess is one of circle, inverted-trapezoid, and inverted-triangle.

According to a preferred embodiment of the present invention, the anode layer is a transparent electrode layer, and the transparent electrode layer is made of indium tin oxide or indium zinc oxide.

According to a preferred embodiment of the present invention, a polarizer is disposed on a surface of the light emitting layer, and the polarizer is made of one of liquid crystal layer and polyvinyl alcohol film or a combination film layer thereof.

According to a preferred embodiment of the present invention, a reflection layer is disposed between the anode layer and the light emitting layer, and the reflection layer is made of aluminum, silver or nickel metal film.

According to an objective of the present invention, a display device is provided and comprises an organic light emitting diode (OLED) display panel and a protection cover plate located on the OLED display panel, wherein: the protection cover plate is convex lens; the OLED display panel comprises a light emitting region and a non-light emitting region, the OLED display panel comprises: an underlay substrate; a thin film transistor (TFT) layer disposed on a side of the underlay substrate; a planarization layer disposed on a side of the TFT layer away from the underlay substrate, and comprising a first recess defined in the planarization layer and corresponding to the light emitting region; an anode layer comprising a bending portion and a horizontal portion, the bending portion covering a surface of the first recess, the horizontal portion extending from two sides of the first recess to the non-light emitting region, and a second recess defined in a surface of the bending portion and corresponding to the light emitting region; a pixel definition layer located on a side of the planarization layer away from the TFT layer, disposed separately along two extension lines of two side walls of the second recess, and covering the horizontal portion; a light emitting layer disposed on a surface of the second recess and disposed opposite to the bending portion; a cathode layer disposed on and fully covering the light emitting layer and a surface of the pixel definition layer; and an encapsulation layer disposed on a surface of the cathode layer.

According to a preferred embodiment of the present invention, the convex lens is a convex structure, and a central angle of the convex lens is from 0° to 180°.

According to a preferred embodiment of the present invention, the convex lens is a hollow semi-sphere.

According to a preferred embodiment of the present invention, a horizontal included angle located near a central angle of the protection cover plate is less than a horizontal included angle located away from the central angle.

According to a preferred embodiment of the present invention, material of the convex lens is transparent glass or a transparent polyimide thin film.

According to a preferred embodiment of the present invention, the TFT layer comprises a light shielding layer disposed on a surface of the underlay substrate, a buffer layer disposed on the surface of the underlay substrate and covering the light shielding layer, an active layer disposed on the buffer layer, a first gate insulation layer disposed on the buffer layer and covering the active layer, a first gate electrode disposed on the first gate insulation layer, a second gate insulation layer disposed on the first gate insulation layer and covering the first gate electrode, a second gate electrode disposed on the second gate insulation layer, an interlayer dielectric layer disposed on the second gate insulation layer and covering the second gate electrode, a source electrode and a drain electrode disposed on the interlayer dielectric layer; wherein an anode via hole is defined in a portion of the planarization layer corresponding to the drain electrode, and a side of the horizontal portion is electrically connected to the drain electrode through the anode via hole.

According to a preferred embodiment of the present invention, the bending portion comprises a first tilt portion, a horizontal connection portion, and a second tilt portion, and the first tilt portion, the horizontal connection portion, and the second tilt portion are formed integrally.

According to a preferred embodiment of the present invention, a first included angle is formed between the first tilt portion and the horizontal connection portion, a second included angle is formed between the second tilt portion and the horizontal connection portion, and each of the first included angle and the second included angle is from 30° to 60°.

According to a preferred embodiment of the present invention, a polarizer is disposed on a surface of the encapsulation layer, and the polarizer is made of one of liquid crystal layer and polyvinyl alcohol film or a combination film layer thereof.

### Advantages

In the present invention, the planarization layer is disposed with a recess, the anode layer fully covers the recess and extend upward along the sidewall of the recess for a predetermined length. The light emitting layer is disposed opposite the anode layer. When the light emitting layer emits out light, a bottom and a side portion of the light emitting layer in a light emitting region generate light, and the light is emitted out at a corresponding angle to increase light emitting area and angle of the light emitting layer and reduce phenomenon of the color shift of the OLED display panel display screen under a great angle of view to increase a viewable angle of view.

### DESCRIPTION OF DRAWINGS

To more clearly elaborate on the technical solutions of embodiments of the present invention or prior art, appended figures necessary for describing the embodiments of the present invention or prior art will be briefly introduced as follows. Apparently, the following appended figures are merely some embodiments of the present invention. A person of ordinary skill in the art may acquire other figures according to the appended figures without any creative effort.

FIG. 1 is a schematic view of working principles of an organic light emitting diode (OLED) display panel provided by the present invention embodiment.

FIG. 2 is a schematic structural view of an OLED display panel provided by the present invention embodiment.

FIG. 3 is a schematic structural view of an OLED display panel provided by the present invention embodiment.

FIG. 4 is a schematic structural view of a display device provided by the present invention embodiment.

### DETAILED DESCRIPTION OF PREFERRED EMBODIMENTS

Each of the following embodiments is described with appending figures to illustrate specific embodiments of the present invention that are applicable. The terminologies of direction mentioned in the present invention, such as “upper”, “lower”, “front”, “rear”, “left”, “right”, “inner”, “outer”, “side surface”, etc., only refer to the directions of the appended figures. Therefore, the terminologies of direction are used for explanation and comprehension of the present invention, instead of limiting the present invention. In the figures, units with similar structures are marked with the same reference characters.

The present invention can solve the technical issue that emitted light of the conventional OLED display panel is only perpendicular to a certain angle, especially in the curve display, to result in color shift of OLED display panel display screen under a large angle of view and the angle of view is poor.

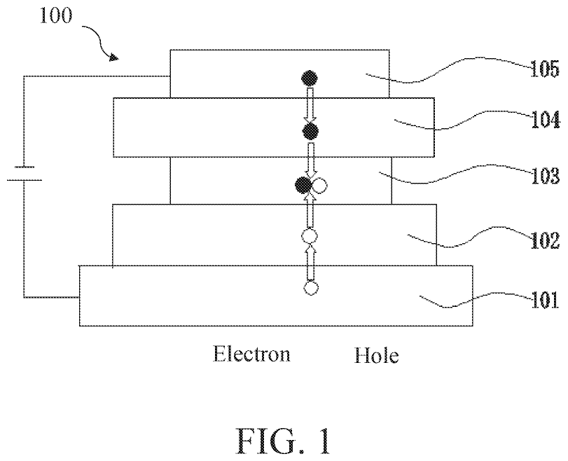

With reference to FIG. 1, FIG. 1 is a schematic view of working principles of an organic light emitting diode (OLED) display panel 100 provided by the present invention embodiment. The OLED display panel 100 comprises an anode layer 101 disposed on an substrate, a hole transport layer 102 disposed on the anode layer 101, a light emitting layer 103 disposed on the hole transport layer 102, an electron transport layer 104 disposed on the light emitting layer 103, and a cathode layer 105 disposed on the electron transport layer 104. An external power source is connected to the anode layer 101 through an end of a layer of thin and transparent indium tin oxide with semiconductor characteristics, and another end thereof is connected to the cathode layer 105. When the anode layer 104 is applied with a direct current voltage of 2V to 10V, the cathode layer 105 generates electrons, and the anode layer 101 generates holes. Under force of an electrical field, the electrons pass through the electron transport layer 104, the holes pass through the hole transport layer 102, and them encounters in the light emitting layer 103, negative charges of the electrons and positive charges of the holes attract each other to excite organic material in the light emitting layer 103 to emit light. Because the cathode layer 105 is transparent, light emitted out from the light emitting layer 103 is visible. By controlling the amount of current of the anode layer 101, brightness of the light emitted from the light emitting layer 103 can be adjusted. The greater the current is, the higher the brightness is, and vice versa. When a voltage is inputted, the holes of the anode layer 101 and the electric charges of the cathode layer 105 are combined in the light emitting layer 103 to emit light. According to different formulas, three primary colors of red, green, and blue (R, G, B) can be generated to form basic colors.

With regard to the technical issue that In a common OLED display panel, light emitted from the light emitting layer, after inputted through the encapsulation layer and the cover plate layer, the outputted light has a specific orientation, most light is vertically emitted out from the screen, and when the OLED display panel is viewed from other angle, original color is not seen and only blur images or even entirely black or white images can be seen, the present invention disposes an anode layer in a pixel recess as a bending portion, and the bending portion covers a portion of a sidewall of the pixel recess. The light emitting layer corresponding to the anode layer is also disposed as a bending light emitting portion. Such design increases light emitting area and angle of the light emitting layer such that phenomenon of the color shift of the OLED display panel display screen under a great angle of view is reduced to achieve great viewable angle of view.

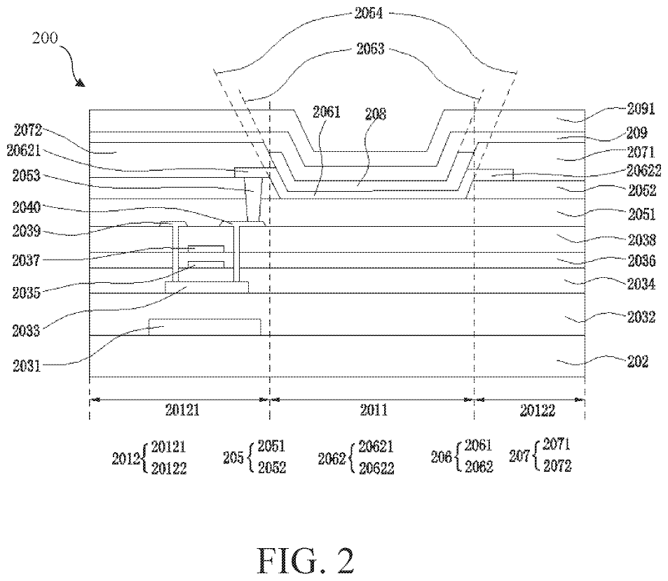

Specifically, with reference to FIG. 2, the present invention provides an OLED display panel 200, the OLED display panel 200 comprises a light emitting region 2011 and a non-light emitting region 2012. The OLED display panel 200 comprises: an underlay substrate 202; a TFT layer disposed on a side of the underlay substrate 202; a planarization layer 205 disposed on a side of the TFT layer away from the underlay substrate 202, and comprising a first recess 2054 defined in the planarization layer 205 and corresponding to the light emitting region 2011; an anode layer 206 comprising a bending portion 2061 and a horizontal portion 2062, the bending portion 2061 covering a surface of the first recess 2054, the horizontal portion 2062 extending from two sides of the first recess 2054 to the non-light emitting region 2012, and a second recess 2063 defined in a surface of the bending portion 2061 and corresponding to the light emitting region 2011; a pixel definition layer 207 located on a side of the planarization layer 205 away from the TFT layer, disposed separately along two extension lines of two side walls of second recess 2063, and covering the horizontal portion 2062; a light emitting layer 208 disposed on a surface of the second recess 2063 and disposed opposite to the bending portion 2061; a cathode layer 209 disposed on and fully covering the light emitting layer 208 and a surface of the pixel definition layer 207; and an encapsulation layer 2091 disposed on a surface of the cathode layer 209.

Specifically, the TFT layer comprises a light shielding layer 2031 disposed on a surface of the underlay substrate 202, a buffer layer 2032 disposed on the surface of the underlay substrate 202 and covering the light shielding layer 2031, an active layer 2033 disposed on the buffer layer 2032, a first gate insulation layer 2034 disposed on the buffer layer 2032 and covering the active layer 2033, a first gate electrode 2035 disposed on the first gate insulation layer 2034, a second gate insulation layer 2036 disposed on the first gate insulation layer 2034 and covering the first gate electrode 2035, a second gate electrode 2037 disposed on the second gate insulation layer 2036, an interlayer dielectric layer 2038 disposed on the second gate insulation layer 2036 and disposed on the second gate electrode 2037, and a source electrode 2039 and a drain electrode 2040 disposed on interlayer dielectric layer 2038; wherein, an anode via hole 2053 is defined in a portion of the planarization layer 205 corresponding to the drain electrode 2040, and a side 20621 of the horizontal portion 2062 is electrically connected to the drain electrode 2040 through the anode via hole 2053, the source electrode 2039 is electrically connected to a doped region of the source electrode in the active layer 2033 through a contact hole of the source electrode, and the drain electrode 2040 is electrically connected to a doped region of the drain electrode in the active layer 2033 through a contact hole of the drain electrode.

In the present embodiment, the underlay substrate 202, underlay substrate 202 is generally a glass substrate, can also be a substrate of other material, and no limitation is made thereto. The TFT layer is disposed on underlay substrate 202, and in the present embodiment the TFT layer is a top-gate type thin film transistor.

The TFT layer comprises a light shielding layer 2031. Material of the light shielding layer 2031 is metal, and is preferably one of molybdenum (Mo), aluminum (Al), copper (Cu), and titanium (Ti) or alloy thereof. A buffer layer 2032 is disposed on the underlay substrate 202 and covers the light shielding layer 2031, the buffer layer 2032 is a silicon oxide (SiOx) thin film, a silicon nitride (SiNx) thin film, or a complex thin film formed by alternately laminated silicon oxide thin films and silicon nitride thin films. An active layer 2033 is disposed on the buffer layer 2032 through the chemical vapor deposition process. The active layer 2033 is deposited on the buffer layer 2032 by a magnetron sputtering process, a metal organic chemical vapor deposition process or a pulsed laser evaporation process. After the active layer 2033 is deposited, and then the annealing process is implemented. The annealing process can be implemented at 400° C. under ambient dry air for about 0.5 hour. After the annealing process is completed, a wet-etching process or a dry-etching process adopting oxalic acid as an etching liquid is implemented to etch the active layer 2033. After the etching process, an entire layer of the metal oxide thin film is patterned to form an island-shaped metal oxide semiconductor layer.

A first gate insulation layer 2034 is disposed on the active layer 2033, first gate insulation layer 2034 undergoes a physical vapor deposition process to form a first gate electrode 2035. A second gate insulation layer 2036 is disposed on the first gate insulation layer 2034. The second gate insulation layer 2036 undergoes a physical vapor deposition process to form a second gate electrode 2037. Both the first gate insulation layer 2034 and the second gate insulation layer 2036 are formed by a chemical vapor deposition process. Then the annealing process at 400° C. under ambient dry air. Material of the first gate insulation layer 2034 and the second gate insulation layer 2036 is silicon oxide, silicon nitride, silicon oxynitride, or a sandwiching structure of the three. Material of the first gate electrode 2035 and the second gate electrode 2037 is metal material, for example, copper (Cu), aluminum (Al), titanium (Ti), tantalum (Ta), tungsten (W), molybdenum (Mo), chromium (Cr), etc.

In the present embodiment, the planarization layer 205 comprises a first planarization layer 2051 and a second planarization layer 2052. The second planarization layer 2052 is located on a surface of the first planarization layer 2051. The first recess 2054 is located in the second planarization layer 2052. Then, an anode layer 206 is disposed on a surface of the first recess 2054, and the anode layer 206 is preferably a transparent electrode layer, the transparent electrode layer is made of indium tin oxide or indium zinc oxide. A second recess 2063 is defined in the anode layer 206 and corresponds to the light emitting region 2011. An inner wall of each of the first recess 2054 and the second recess 2063 is tilted or curved toward a center of the first recess 2054 or the second recess 2063. a geometrical shape of each of the first recess 2054 and the second recess 2063 is one of circle, inverted-trapezoid, and inverted-triangle. In the present embodiment, the first recess 2054 and the second recess 2063 are inverted-trapezoids.

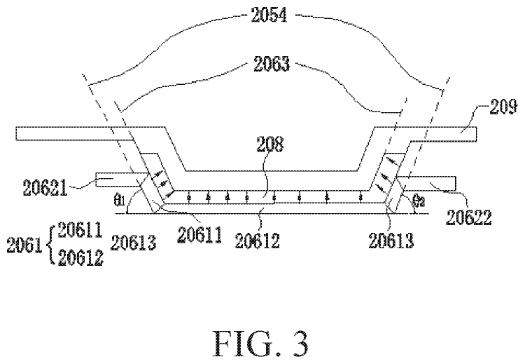

With reference to FIGS. 2 and 3, the anode layer 206 comprises a bending portion 2061 and a horizontal portion 2062. The bending portion 2062 covers a surface of the first recess 2054. The horizontal portion 2062 extending from two sides of the first recess to the non-light emitting region. The bending portion 2061 comprises a first tilt portion 20611, a horizontal connection portion 20612, and a second tilt portion 20613. The first tilt portion 20611, the horizontal connection portion 20612, and the second tilt portion 20613 are formed integrally. The first tilt portion 20611 and the second tilt portion 20613 are symmetrical to a central line of the horizontal connection portion 20612. A first included angle θ1 is formed between the first tilt portion 20611 and the horizontal connection portion 20612. A second included angle θ2 is formed between the second tilt portion 20613 and the horizontal connection portion 20612. Each of the first included angle 81 and the second included angle θ2 is from 30° to 60°.

To increase a displaying angle of view of the OLED display panel 100, a reflection layer can be further disposed between the anode layer 206 and the light emitting layer 208. The reflection layer is an aluminum, silver or nickel metal film. A polarizer can also be disposed on the surface of the encapsulation layer 2091, and the polarizer is one or two combination film layers in the liquid crystal layer or the polyvinyl alcohol film.

In the present embodiment, each of the anode layer 206, the hole transport layer (not shown in FIG. 2), the light emitting layer 208, the electron transport layer (not shown in FIG. 2), and the cathode layer 209 is bent into multiple sections, top surfaces thereof are upward apertures, a top surface width of each aperture is greater than a bottom surface width of the aperture. The cathode layer 209 fully covers the entire OLED display panel 200, and covers the light emitting layer 208 and the pixel definition layer 207. In the present embodiment, the anode layer 206, the hole transport layer (not shown in FIG. 2), the light emitting layer 208, the electron transport layer (not shown in FIG. 2), and the cathode layer 209 are not only oblique-line or straight-line bending, and can also be curve bending or circular bending. When the light emitting layer 208 emits out light, the light emitting layer 208 generates light and emit the light at a corresponding angle. The light passes through the curved surface of multi-section bending, i.e., the continuous bumpy surface, and the outputted light would have refraction and scattering, light emitting angle becomes greater, a light emitting area and angle of the light emitting layer 208 increases, and phenomenon of the color shift of the OLED display panel display screen under a great angle of view is reduced to increase viewable angle of view.

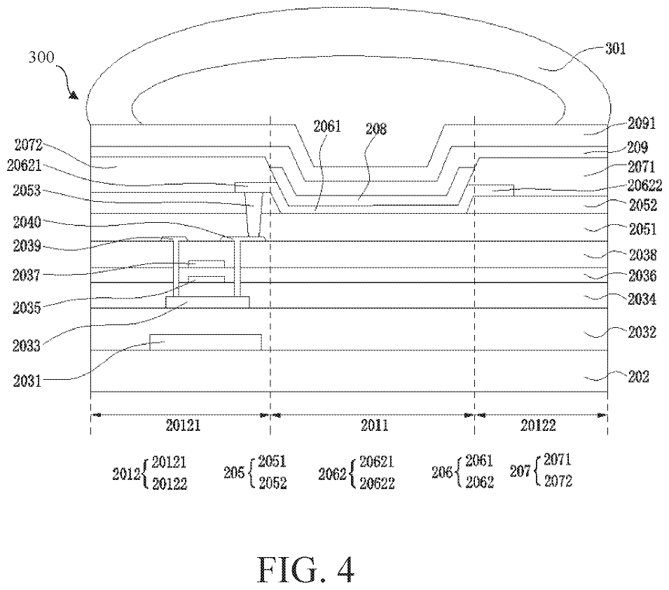

According to the objective of the present invention, a display device is also provided. With reference to FIG. 4, the display device 300 comprises: the above OLED display panel 200, and a protection cover plate 301 located above the OLED display panel 200. The protection cover plate 301 is a convex lens.

Material of the convex lens is transparent glass or a transparent polyimide thin film. The convex lens is a convex structure, and a central angle of the convex lens is from 0° to 180°. The convex lens is a hollow semi-sphere, and a horizontal included angle located near a central angle of the protection cover plate 301 is less than a horizontal included angle located away from the central angle.

Advantages of the present invention are as follows. In the present invention, the planarization layer is disposed with a recess, the anode layer fully covers the recess and extend upward along the sidewall of the recess for a predetermined length. The light emitting layer is disposed opposite the anode layer. When the light emitting layer emits out light, a bottom and a side portion of the light emitting layer in a light emitting region generate light, and the light is emitted out at a corresponding angle to increase light emitting area and angle of the light emitting layer and reduce phenomenon of the color shift of the OLED display panel display screen under a great angle of view to increase a viewable angle of view.

Although the preferred embodiments of the present invention have been disclosed as above, the aforementioned preferred embodiments are not used to limit the present invention. The person of ordinary skill in the art may make various changes and modifications without departing from the spirit and scope of the present invention. Therefore, the scope of protection of the present invention is defined by the scope of the claims.

What is claimed is:

1. An organic light emitting diode (OLED) display panel, comprising a light emitting region and a non-light emitting region, wherein the OLED display panel comprises:
an underlay substrate comprising the light emitting region and the non-light emitting region;
a thin film transistor (TFT) layer disposed on a side of the underlay substrate;
a planarization layer disposed on a side of the TFT layer away from the underlay substrate, and comprising a first recess defined in the planarization layer and corresponding to the light emitting region;
an anode layer comprising a bending portion and a horizontal portion, the bending portion covering a surface of the first recess, the horizontal portion extending from two sides of the first recess to the non-light emitting region, and a second recess defined in a surface of the bending portion and corresponding to the light emitting region;
a pixel definition layer located on a side of the planarization layer away from the TFT layer, disposed separately along two extension lines of two side walls of the second recess, and covering the horizontal portion;
a light emitting layer disposed on a surface of the second recess and disposed opposite to the bending portion;
a cathode layer disposed on and fully covering the light emitting layer and a surface of the pixel definition layer; and
an encapsulation layer disposed on a surface of the cathode layer.

2. The OLED display panel as claimed in claim 1, wherein the TFT layer comprises a light shielding layer disposed on a surface of the underlay substrate, a buffer layer disposed on the surface of the underlay substrate and covering the light shielding layer, an active layer disposed on the buffer layer, a first gate insulation layer disposed on the buffer layer and covering the active layer, a first gate electrode disposed on the first gate insulation layer, a second gate insulation layer disposed on the first gate insulation layer and covering the first gate electrode, a second gate electrode disposed on the second gate insulation layer, an interlayer dielectric layer disposed on the second gate insulation layer and covering the second gate electrode, a source electrode and a drain electrode disposed on the interlayer dielectric layer; wherein an anode via hole is defined in a portion of the planarization layer corresponding to the drain electrode, and a side of the horizontal portion is electrically connected to the drain electrode through the anode via hole.

3. The OLED display panel as claimed in claim 1, wherein the planarization layer comprises a first planarization layer and a second planarization layer, and the first recess is located in the second planarization layer.

4. The OLED display panel as claimed in claim 1, wherein the bending portion comprises a first tilt portion, a horizontal connection portion, and a second tilt portion, and the first tilt portion, the horizontal connection portion, and the second tilt portion are formed integrally.

5. The OLED display panel as claimed in claim 4, wherein the first tilt portion and the second tilt portion are symmetrical to a central line of the horizontal connection portion.

6. The OLED display panel as claimed in claim 4, wherein a first included angle is formed between the first tilt portion and the horizontal connection portion, a second included angle is formed between the second tilt portion and the horizontal connection portion, and each of the first included angle and the second included angle is from 30° to 60°.

7. The OLED display panel as claimed in claim 1, wherein an inner wall of the first recess is tilted or curved toward a center of the first recess, and an inner wall of the second recess is tilted or curved toward a center of the second recess.

8. The OLED display panel as claimed in claim 7, wherein a geometrical shape of each of the first recess and the second recess is one of circle, inverted-trapezoid, and inverted-triangle.

9. The OLED display panel as claimed in claim 1, wherein the anode layer is a transparent electrode layer, and the transparent electrode layer is made of indium tin oxide or indium zinc oxide.

10. The OLED display panel as claimed in claim 1, wherein a polarizer is disposed on a surface of the light emitting layer, and the polarizer is made of one of liquid crystal layer and polyvinyl alcohol film or a combination film layer thereof.

11. The OLED display panel as claimed in claim 1, wherein a reflection layer is disposed between the anode layer and the light emitting layer, and the reflection layer is made of aluminum, silver or nickel metal film.

12. A display device, comprising an organic light emitting diode (OLED) display panel and a protection cover plate located on the OLED display panel, wherein: the protection cover plate is convex lens; the OLED display panel comprises a light emitting region and a non-light emitting region, the OLED display panel comprises: an underlay substrate; a thin film transistor (TFT) layer disposed on a side of the underlay substrate; a planarization layer disposed on a side of the TFT layer away from the underlay substrate, and comprising a first recess defined in the planarization layer and corresponding to the light emitting region; an anode layer comprising a bending portion and a horizontal portion, the bending portion covering a surface of the first recess, the horizontal portion extending from two sides of the first recess to the non-light emitting region, and a second recess defined in a surface of the bending portion and corresponding to the light emitting region; a pixel definition layer located on a side of the planarization layer away from the TFT layer, disposed separately along two extension lines of two side walls of the second recess, and covering the horizontal portion; a light emitting layer disposed on a surface of the second recess and disposed opposite to the bending portion; a cathode layer disposed on and fully covering the light emitting layer and a surface of the pixel definition layer; and an encapsulation layer disposed on a surface of the cathode layer.

13. The display device as claimed in claim 12, wherein the convex lens is a convex structure, and a central angle of the convex lens is from 0° to 180° .

14. The display device as claimed in claim 13, wherein the convex lens is a hollow semi-sphere.

15. The display device as claimed in claim 14, wherein a horizontal included angle located near a central angle of the protection cover plate is less than a horizontal included angle located away from the central angle.

16. The display device as claimed in claim 12, wherein material of the convex lens is transparent glass or a transparent polyimide thin film.

17. The display device as claimed in claim 12, wherein the TFT layer comprises a light shielding layer disposed on a surface of the underlay substrate, a buffer layer disposed on the surface of the underlay substrate and covering the light shielding layer, an active layer disposed on the buffer layer, a first gate insulation layer disposed on the buffer layer and covering the active layer, a first gate electrode disposed on the first gate insulation layer, a second gate insulation layer disposed on the first gate insulation layer and covering the first gate electrode, a second gate electrode disposed on the second gate insulation layer, an interlayer dielectric layer disposed on the second gate insulation layer and covering the second gate electrode, a source electrode and a drain electrode disposed on the interlayer dielectric layer; wherein an anode via hole is defined in a portion of the planarization layer corresponding to the drain electrode, and a side of the horizontal portion is electrically connected to the drain electrode through the anode via hole.

18. The display device as claimed in claim 12, wherein the bending portion comprises a first tilt portion, a horizontal connection portion, and a second tilt portion, and the first tilt portion, the horizontal connection portion, and the second tilt portion are formed integrally.

19. The display device as claimed in claim 17, wherein a first included angle is formed between the first tilt portion and the horizontal connection portion, a second included angle is formed between the second tilt portion and the horizontal connection portion, and each of the first included angle and the second included angle is from 30° to 60°.

20. The display device as claimed in claim 17, wherein a polarizer is disposed on a surface of the encapsulation layer, and the polarizer is made of one of liquid crystal layer and polyvinyl alcohol film or a combination film layer thereof.
